(19) United States
(12) Patent Application Publication
(10) Pub. No.: US 2003/0086302 A1
(43) Pub. Date: May 8, 2003

(54) Data write/read control method and memory device

(75) Inventors: Takahiro Kurakata, Kawasaki (JP); Takashi Kaku, Kawasaki (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/273,187

(22) Filed: Oct. 18, 2002

Related U.S. Application Data
(63) Continuation of application No. PCT/JP00/02577, filed on Apr. 19, 2000.

(51) Int. Cl. G11C 7/00

(52) U.S. Cl. 365/189.02

(57) ABSTRACT

The n-bit data is converted to specific patterns of n+m-bit data when the data is written to the memory device. These specific patterns are those n+m-bit data patterns that have the more numbers of logic values that have the smaller amount of current consumed. Additionally, when the n+m-bit data is read, it is converted back to the original n-bit data. This process makes it possible to reduce the number of write/read operations for the logic values that consume the greater amount of electric current when writing/reading the data to/from the memory device, thereby reducing the amount of power consumed.

### TECHNICAL FIELD

The present invention relates to a data write/read control method for a memory device which is housed in a computer device or the like, and more particularly to a power-saving write/read control method and a memory device using the method.

### BACKGROUND ART

FIG. 7 is a schematic diagram of a memory device. In FIG. 7, a memory device 10 has a memory matrix 11 structured with n (bits) by m (words) memory cells. A row decoder 12 selects a word line for accessing a memory cell in the row direction in the memory matrix 11 based on an inputted address signal A. When a group of memory cells in the horizontal direction is selected by a word line, the data in the memory cells are sent to the bit lines, and a column decoder 13 selects the bit lines (the write/read lines) for accessing the memory cells in the column direction in the memory matrix 11 based on the inputted address signal A. A sense amp 14 detects and amplifies changes in the voltage in the bit lines.

The I/O control circuit 15 is the circuit that controls the read and write operations for the memory cells selected by the row and column. In a read operation, the I/O control circuit 15 causes the data Dout, which has been read from the memory cell, to be outputted from the output terminals, and in a write operation, the I/O control circuit 15 sends the data Din, which has been inputted through the input terminals, to the memory cell, and causes the data Din to be stored therein.

Precharge-type memory devices are well known for increasing the speed of the read operation in this type of memory device. In a precharge-type memory device, the bit lines are precharged to a logic value “1” (high level) before the data in the memory cells are read, and during the read operation those bit lines for which the data is logic “0” (low level) are discharged. If a bit line has been discharged, the bit line must be precharged again before the next read operation. On the other hand, when the data read is logic “1”, the bit line is not discharged, so there is no need to perform a precharge again.

Because of the above, the amount of power consumed in the precharge increases with the number of reading operations of logic values “0” in precharge-type memory devices. More generally, in a type of memory device in which the electric current used for a bit line with a logic value of “1” is different from the electric current for a bit line with a logic value of “0”, the more the number of read operations for the data using the larger electric current, the greater the power required.

### DISCLOSURE OF THE INVENTION

An object of the present invention is to provide a data write/read control method that reduces the power consumed in a memory device of a type wherein the electric current is different in a bit line with logic “1” from the electric current for a bit line with logic “0”, and to provide a memory device that uses this method.

To achieve the aforementioned object, in the present invention the n-bit data is converted to specific patterns of n+m-bit data when the data is written. These specific patterns are those n+m-bit data patterns that have the more numbers of logic values that have the smaller amount of current consumed. Additionally, when the n+m-bit data is read, it is converted back to the original n-bit data. This process makes it possible to reduce the number of write/read operations for the logic values that consume the greater amount of electric current when writing/reading the data to/from the memory device, thereby reducing the amount of power consumed.

A preferable embodiment of the present invention by which to achieve the object described above is a control method for writing/reading data to/from a memory device wherein the electric current consumed in writing/reading a first logic value is greater than the electric current consumed in writing/reading a second logic value, wherein n-bit data of a specific pattern are converted into n+m-bit data (where n and m are natural numbers) of a pattern, of all the n+m-bit patterns, that contain more numbers of the second logic values, which are then written to the memory device, and wherein the n+m-bit data read from the memory device are converted back into the n-bit data of the aforementioned specific pattern.

A preferred memory device of the present invention, in order to achieve the object described above, is a memory device which has a plurality of memory cells, and in which each memory cell stores a first logic value or a second logic value and current consumed in writing/reading the a first logic value to/from each memory cell is greater than current consumed in writing/reading the second logic value to/from each memory cell, and this memory device comprises a converter that converts n-bit data of a specific pattern into n+m-bit data (where n and m are natural numbers) of a pattern, of all the n+m-bit patterns, that has more numbers of the second logic values than the first logic numbers; a writing/reading unit that writes the n+m-bit data to a group of memory cells and reads said n+m-bit data from the group of memory cells; and a reverse converter that converts the n+m-bit data back into the aforementioned n-bit data.

The method and memory device of the present invention, as described above, reduce the number of write/read operations for the logic value that consumes the larger amount of electrical current when writing/reading, and are thereby able to reduce the amount of power consumed.

### BRIEF DESCRIPTION OF DRAWINGS

FIG. 1 is a structural drawing of a memory device of an embodiment of the present invention;

FIG. 2 is a table showing 3-bit data patterns and the consumption current values thereof;

FIG. 3 is a table showing 4-bit data patterns and the values of the consumption currents thereof;

FIG. 4 is a chart showing 23 selections of 4-bit data patterns and the values of the consumption currents thereof;

FIG. 5 is an example of the conversion table in the encoder 16 and the decoder 17;

FIG. 6 is a table showing the values for the electric currents for the 2ⁿ selected data patterns (in which the values for the electric currents are reduced), selected from all of the n+m-bit data patterns where m redundant bits have-been added to the n data bits; and

FIG. 7 is a schematic drawing of a memory device.

### BEST MODE FOR CARRYING OUT THE INVENTION

An embodiment of the present invention will be described below using the drawings. Note, however, that the technical scope of the present invention is in nowise limited by this embodiment.

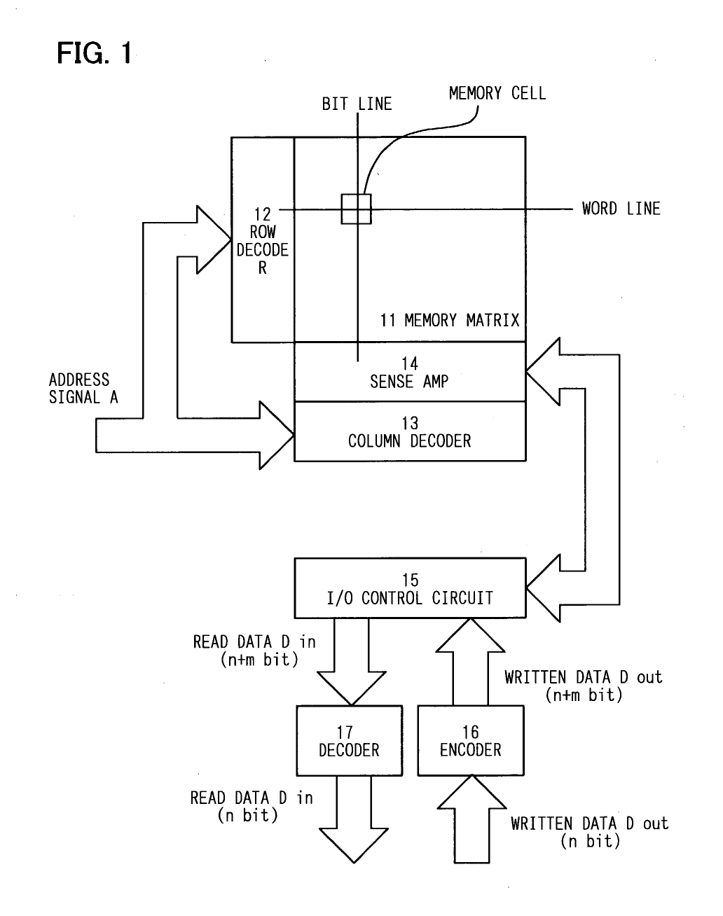

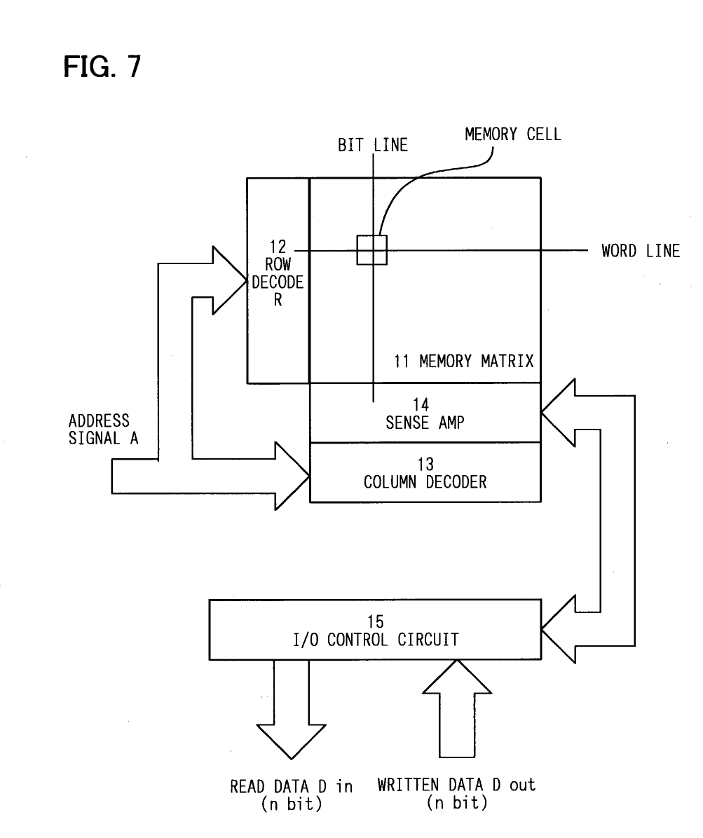

FIG. 1 is a structural drawing of a memory device according to an embodiment of the present invention. In FIG. 1, a memory device 10 comprises a memory matrix 11 comprising n (bits)×m (words) memory cells, a row decoder 12, a column decoder 13, a sense amp 14, and an I/O control circuit 15, as did the memory device of FIG. 7. Each memory cell in the memory device 10 of the present invention is also provided with an encoder 16 and a decoder 17, connected to the I/O control circuit. The encoder 16 converts inputted data using the conversion method of the present invention, described below. The I/O control circuit 15 stores the converted data in a memory cell. Additionally, the decoder 17 converts back the data that is read from a memory cell. The data that has been read is converted data, having been converted by the encoder 16. Because of this, the converted data is converted back to the original data by the decoder 17.

The data write/read method according to the embodiment of the present invention in a memory device such as that described above will be explained below. The encoder 16 converts the inputted n-bit data into n+m-bit data, where “m” is the number of redundant bits, and is a counting number. When the number of bits in the data is increased from n bits to n+m-bits, the total number of data patterns increases from 2ⁿ patterns to 2^{n+m} patterns. In the embodiment of the present invention, the 2ⁿ data patterns that consume less current are selected from the 2^{n+m} data patterns, and are assigned to the various n-bit data patterns. Because electric current is consumed when writing/reading a logic value “0”, the fewer the logic values “0” included in a data pattern (i.e., the more the logic values “1”), the less the current consumed by the data pattern.

The invention will be explained below using a specific case wherein 3-bit data is converted into 4-bit data (n=3, m=1).

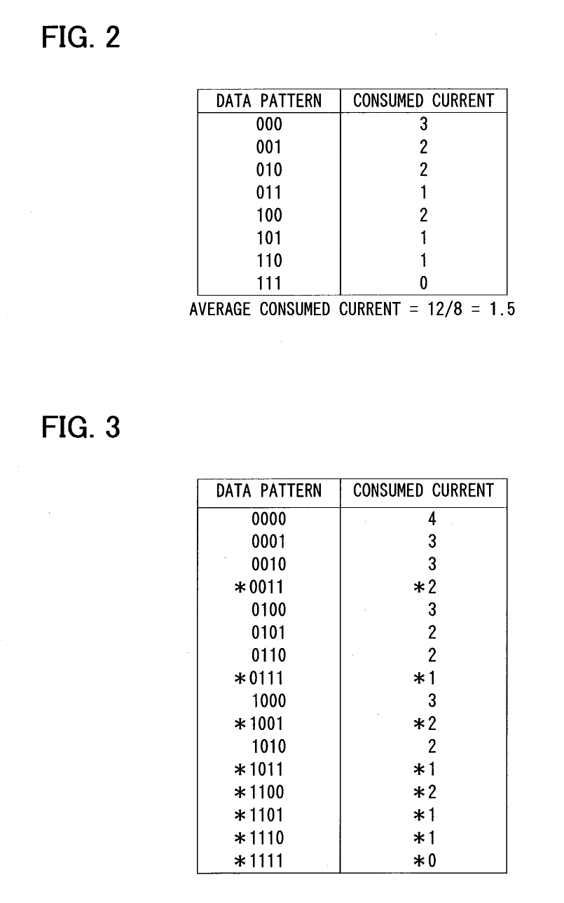

FIG. 2 shows the 3-bit data patterns and the amounts of current consumed therein. FIG. 3 shows the 4-bit data patterns and the amounts of current consumed therein. The values for the consumption currents shown in FIGS. 2 and 3 are assumed values for the purpose of explanation, and it is assumed that current consumed when there is a current when writing or reading data to a memory cell (i.e., for logic “0”) has a value of “1,” and consumption current when there is no current (i.e., for logic “1”) has a value of “0.” When this is done, the value for the current consumed for each of the data patterns is determined by the number of zeros, as shown in FIGS. 2 and 3. The total of the current consumed in all data patterns is the total number of zeros.

The average value of current consumed in all of the 3 bit patterns shown in FIG. 2 is (3+2+2+1+2+1+1+0)/2³=1.5. On the other hand, of the 4-bit data patterns shown in FIG. 3, the 2³=8 data patterns with the lowest consumption currents are selected. The selected data patterns are those marked with the asterisks* in the figure.

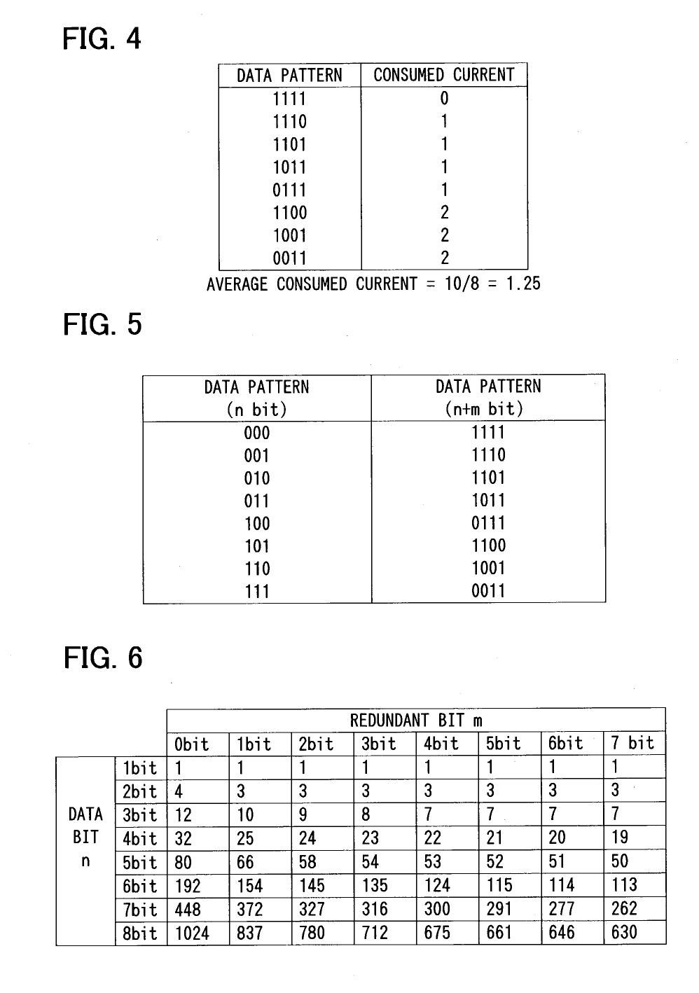

FIG. 4 shows the 23 selected 4-bit data patterns, with the amounts of current consumed therein. The average value for the current consumed in the 23 selected 4-bit data patterns in FIG. 4 is (0+1+1+1+1+2+2+2)/8=1.25. Consequently, the average value of the current consumed in the 2³ selected 4-bit data patterns is less than that for the 2³ 3-bit data patterns. As a result, the average value for the current consumed when writing data to a memory cell or reading written data from a memory cell can be reduced by converting each of the 3-bit data patterns in FIG. 2 to the data patterns shown in FIG. 4.

FIG. 5 is an example of a conversion table in the encoder 16 and the decoder 17. The conversion table in FIG. 5 defines the relationship between the 3-bit data patterns in FIG. 2 and the 4-bit data patterns in FIG. 4. The encoder 16 converts each inputted 3-bit data pattern into a 4-bit data pattern according to the table in FIG. 5. The I/O control circuit 15 writes the converted 4-bit data to the memory cell, and, when reading data from a memory cell, reads the converted 4-bit data. This can reduce the power consumption because the number of read/write procedures for the logic value that consumes electrical current when writing/reading data to/from the memory device is reduced. After reading, the 4-bit data is converted back into the original 3-bit data by the decoder 17, in accordance with the table in FIG. 5.

FIG. 6 shows the total amount of electric current when the 2ⁿ data patterns that consume the least electric current (i.e., the ones that have the more the logic values of “1”) are selected from all of the n+m-bit data patterns wherein m redundant bits have been added to the n data bits.

The total electric current of the 2ⁿ data patterns selected from all of the data patterns with n+m data bits (i.e., from the 2^{n+m} possibilities) is minimized when the value for the electric current in each of the 2ⁿ selected data patterns is either “0” or “1.” The value for the electric current is “0” when all of the n+m-bits are “1”, which only exists for a single combination. For example, if n=3 and m=4, then “1 1 1 1 1 1 1” is the only such data pattern for all of the data patterns with n+m=7 bits.

The value for the electric current is “1” only when only one of the n+m-bits of data is logic “0”; this happens in n+m combinations. For example, if n=3 and m=4, then of all of the n+m(=7)-bit data patterns, there are only the following:

“0 1 1 1 1 1 1”

“1 0 1 1 1 1 1”

“1 1 0 1 1 1 1”

“1 1 1 0 1 1 1”

“1 1 1 0 1 1”

“1 1 1 1 0 1”

“1 1 1 1 1 1 0”

In the examples above, the value for the electric current in all of the 2ⁿ selected data patterns (where n=3) is either “0” or “1,” so the total of the values for the electric currents is minimized. In this example, even though the number of data patterns in which the value of the electric current is “1” would be increased by making the number of redundant bits (m) more than 4, the sum of the values for the electric currents would not be any smaller because the number of data patterns selected would still be 2ⁿ.

If 2ⁿ≦1+n+m, then the sum of the values for the electric currents will be the minimal value n+m (=2ⁿ−1). In other words, in the range where 2ⁿ 1+n+m, increasing the number of redundant bits m reduces the sum of the values of the electric currents corresponding to the number of data bits n. For example, if the number of data bits n=8, then

2⁸≦1+8+m

so m 256−9=247 bits. Consequently, if there are 8 data bits, then having the number of redundant bit m be at least 247 will reduce the sum of the values for the electric currents from 1024 to n+m (=255). Insofar as the number of redundant bits m does not exceed 247, the more the numbers, the further the sum of the values of the electric currents can be reduced.

As described above, the 2ⁿ data patterns with the least current consumed (i.e., the patterns with the most logic values of “1”) are selected from the n+m-bit data patterns wherein m redundant bits have been added to the n data bits, and one n+m-bit data pattern is assigned to each of the data patterns with n data bits. The encoder 16 and the decoder 17 are provided with conversion tables for the n+m-bit data patterns corresponding to the n-bit data patterns, and the encoder 16 converts the inputted n-bit data into n+m-bit data according to the conversion table. By doing this, data patterns that consume less current when writing/reading than the original n-bit data patterns are stored into the memory cells. The decoder 17 returns the n+m-bit data read out back into n-bit data according to the conversion table.

The embodiment described above can be applied to a memory device wherein the value for the current consumed when writing/reading a logic value “1” differs from the value of the current consumed when writing/reading a logic value “0”. In other words, this embodiment can be applied to (1) memory devices, such as described above, wherein no current is consumed when writing/reading logic values “1” but current is consumed when writing/reading logic values “0”, (2) memory devices wherein no current is consumed when writing/reading logic 0 values but current is consumed when writing/reading logic values “1”, or (3) memory devices wherein current is consumed when writing/reading both logic values “0” and logic values “1”, but the amount of current consumed is different in each case. Such memory devices include, for example, precharged RAM (SRAM, DRAM, etc.), ROM (flash memory, etc.) and other types of semiconductor memory.

### INDUSTRIAL APPLICABILITY

As described above, the present invention makes it possible to reduce the amount of power consumed in a memory device wherein the amount of current consumed when writing/reading a logic 1 differs from the amount of current consumed when writing/reading a logic value “0”.

The scope of protection of the present invention is not limited to the embodiment described above, but extends to the inventions described in the patent claims, and to equivalents thereof.

What is claimed is:

1. A data write/read control method for a memory device in which the current consumed for writing/reading a first logic value is greater than the current consumed for writing/reading a second logic value, comprising the steps of:
converting n-bit data of a specific pattern into n+m-bit data (where n and m are natural numbers) of a pattern including the more numbers of the second logic values than the first logic values of all the n+m-bit patterns, the converted n+m-bit data being written in said memory device; and
reversely converting the n+m-bit data read from said memory device back into n-bit data of said specific pattern.

2. A memory device which has a plurality of memory cells and stores a first logic value or a second logic value in each of the memory cells, and in which the current consumed in writing/reading the first logic value to/from each memory cell is greater than the current consumed in writing/reading the second logic value to/from each memory cell, comprising:
a converter converting n-bit data of a specific pattern into n+m-bit data (where n and m are natural numbers) of a pattern including the more numbers of the second logic values than the first logic values of all the n+m-bit patterns;
a writing/reading unit for writing said n+m-bit data to a group of memory cells and for reading said n+m-bit data from said group of memory cells; and
a reverse converter for reversely converting said n+m-bit data back into said n-bit data.

3. The memory device according to claim 2, wherein a table is provided that relates each of the patterns with n bits to one of the 2ⁿ n+m-bit patterns including the more numbers of the second logic values;
said converter converts said n-bit data into said n+m-bit data according to said table; and
said reverse converter reversely converts said n+m-bit data back into said n-bit data according to said table.

4. The memory device according to claim 2, wherein said n+m bits do not exceed (2ⁿ−1) bits.

5. The memory device according to claim 2, wherein the write/read lines in each memory cell are precharged to the second logic value before said writing/reading unit writes/reads data to/from each memory cell.
